(19) United States
(12) Patent Application Publication
(10) Pub. No.: US 2019/0074217 A1
(43) Pub. Date: Mar. 7, 2019

(54) CONDUCTIVE CONNECTORS HAVING A RUTHENIUM/ALUMINUM-CONTAINING LINER AND METHODS OF FABRICATING THE SAME

(71) Applicant: Intel Corporation, Santa Clara, CA (US)

(72) Inventors: Christopher J. Jezewski, Hillsboro, OR (US); Ramanan V. Chebiam, Hillsboro, OR (US); Jasmeet S. Chawla, Hillsboro, OR (US); Mauro J. Kobrinsky, Portland, OR (US); James S. Clarke, Portland, OR (US)

(73) Assignee: Intel Corporation, Santa Clara, CA (US)

(21) Appl. No.: 16/072,145

(22) PCT Filed: Feb. 25, 2016
(86) PCT No.: PCT/US16/19617

§ 371 Date: Jul. 23, 2018

(51) Int. Cl. H01L 21/768; H01L 21/288; H01L 23/532; C23C 18/40

(52) U.S. Cl. CPC H01L 21/76843; H01L 21/288; C23C 18/40; H01L 21/76867; H01L 23/53238; H01L 21/76883

(57) ABSTRACT

A conductive connector for a microelectronic structure may be formed in an opening in a dielectric layer, wherein a ruthenium/aluminum-containing liner is disposed between the dielectric layer and a substantially aluminum-free copper fill material within the opening. The ruthenium/aluminum-containing liner may be formed by depositing a ruthenium-containing liner and migrating aluminum into the ruthenium-containing liner with an annealing process. The aluminum may be presented as a layer formed either before or after the deposition of a copper fill material, or may be presented within a copper/aluminum alloy fill material wherein the annealing process migrates the aluminum out of the copper/aluminum alloy and into the ruthenium-containing liner.

### TECHNICAL FIELD

Embodiments of the present description relate to the field of microelectronic devices, and, more particularly, to the fabricating conductive connectors, such as contact structures and conductive routes, used in the formation of microelectronic devices.

### BACKGROUND

The microelectronic industry is continually striving to produce ever faster and smaller microelectronic devices for use in various electronic products, including, but not limited to portable products, such as portable computers, digital cameras, electronic tablets, cellular phones, and the like. As the size of components, such as microelectronic dice and microelectronic substrates, are reduced, the size of conductive connectors, such as contact structures and conductive routes (conductive traces and conductive vias), must also be reduced. However, the reduction of the size of the conductive connectors may result high resistivity due to voids forming in the conductive connectors due to poor metal adhesion and/or poor gap filling. Such high resistivity may result in the electrical connectors being incapable of carrying effective electrical signals for the operation of the microelectronic devices. Therefore, there is a need to develop conductive connectors and methods of fabrication of the same which are capable of carrying effective electrical signals.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The present disclosure will be described with additional specificity and detail through use of the accompanying drawings, such that the advantages of the present disclosure can be more readily ascertained, in which:

FIGS. 1-8 illustrate side cross sectional views of a method of forming a conductive connector, according to an embodiment of the present description.

FIG. 9 illustrates a side cross sectional view of a conductive connector formed by an alternate method, according to an embodiment of the present description.

FIG. 10 illustrates a side cross sectional view of a conductive connector formed by another alternate method, according to an embodiment of the present description.

FIG. 11 illustrates a side cross sectional view of a conductive connector, according to another embodiment of the present description.

FIG. 12 illustrates a computing device in accordance with one implementation of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer or component with respect to other layers or components. One layer/component “over” or “on” another layer/component or bonded “to” another layer/component may be directly in contact with the other layer/component or may have one or more intervening layers/components. One layer/component “between” layers/components may be directly in contact with the layers/components or may have one or more intervening layers/components.

Microelectronic devices are generally fabricated from various microelectronic components, including, but not limited to, at least one microelectronic die (such as a microprocessor, a chipset, a graphics device, a wireless device, a memory device, an application specific integrated circuit, or the like), at least one passive component (such as resistors, capacitors, inductors and the like), and at least one microelectronic substrate (such as interposers, motherboards, and the like) for mounting the components. Electrical signals, power delivery, and ground lines are provided through conductive connectors that may be formed in or on the microelectronic components. As will be understood to those skilled in the art, such conductive connectors may including contact structures (such as contact structures that deliver electrical signals to a gate electrode), conductive route structures (such as a plurality of conductive traces formed on layers of dielectric material that are connected by conductive vias) for the interconnection of various microelectronic components, or any other structures that may be used for electrical signals, power delivery, and/or ground lines.

Current methods of forming conductive connectors for a microelectronic structure involve forming multiple material layers within a via in a dielectric layer. For example, a barrier layer may be formed from a tantalum nitride layer followed by a layer of tantalum. After the formation of the barrier layer, a copper alloy layer may be deposited on the barrier layer, followed by a copper seed layer. From the copper seed layer, the via may be filled with copper, such as by plating. However, having multiple layers make it difficult scale down, as voiding may occur. As will be understood to those skilled in the art, voiding may increase the resistance of a conductive connector relative to a conductive connector having no voids.

Embodiments of the present description include a conductive connector for a microelectronic structure formed in an opening in a dielectric layer, wherein the conductive connector includes a ruthenium/aluminum-containing liner disposed between the dielectric layer and a substantially aluminum-free copper fill material within the opening. The ruthenium/aluminum-containing liner may be formed by depositing a ruthenium-containing liner and migrating aluminum into the ruthenium-containing liner with an annealing process. The aluminum may be presented as a layer formed either before or after the deposition of a copper fill material, or may be presented within a copper/aluminum alloy fill material wherein the annealing process migrates the aluminum out of the copper/aluminum alloy and into the ruthenium-containing liner. In further embodiments of the present description, the conductive connector may have a barrier layer disposed between the ruthenium/aluminum liner and dielectric layer of the microelectronic structure. The use of the ruthenium/aluminum liner may improve gapfill and adhesion due to its wetting and adhesion properties, which may result in the conductive connector being substantially free of voids. Furthermore, the utilization of aluminum in the ruthenium/aluminum liner may improve its barrier properties in preventing diffusion of the copper fill material.

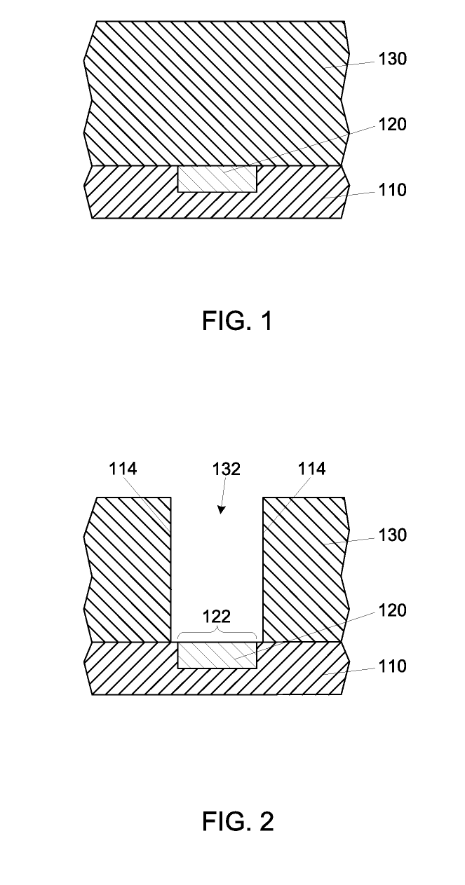

FIGS. 1-7 illustrate a method of fabricating a conductive connector according to one embodiment of the present description. As shown in FIG. 1, a first dielectric material layer 110 may be formed having at least one conductive land 120 formed therein and a second dielectric material layer 130 may be formed over the first dielectric material layer 110 and the conductive land 120. The first dielectric material layer 110 and the second dielectric material layer 130 may be any appropriate dielectric material, including but not limited to, silicon dioxide (SiO₂), silicon oxynitride (SiOₓN_{y}), and silicon nitride (Si₃N₄) and silicon carbide (SiC), liquid crystal polymer, epoxy resin, bismaleimide triazine resin, polyimide materials, and the like, as well as low-k and ultra low-k dielectrics (dielectric constants less than about 3.6), including but not limited to carbon doped dielectrics, fluorine doped dielectrics, porous dielectrics, organic polymeric dielectrics, silicon based polymeric dielectrics, and the like. The first dielectric material layer 110 and the second dielectric material layer 130 may be formed by any known technique, including, but not limited, chemical vapor deposition, physical vapor deposition, coating, lamination, and the like.

It is understood that the conductive land 120 could be any appropriate microelectronic structure. In one embodiment, the conductive land 120 may be a transistor structure, such as a transistor gate electrode. In such an embodiment, the conductive land 120 may be a workfunction metal, including, but not limited to, titanium, aluminum, tantalum, zirconium, and the like. In another embodiment, the conductive land 120 may be a part of a conductive route structure, such as a front end and/or back end metallization. In such an embodiment, the conductive land 120 may include, but is not limited to, copper, silver, nickel, gold, aluminum, tungsten, cobalt, and alloys thereof, and the like.

As shown in FIG. 2, at least one opening 132, such as a trench or a via, may be formed through the second dielectric material layer 130 to expose at least a portion 122 of the conductive land 120. As will be understood to those skilled in the art, the opening 132 may be a part of and extend from a trench. The openings 132 may be formed by any known technique, such as photolithography, etching, and laser ablation. It is understood that an etch stop layer (not shown) may be formed over the first dielectric material layer 110 and the conductive land 120, and the second dielectric material layer 130 may be formed over the etch stop layer (not shown). The processes and materials used and the purpose for forming the etch stop layer (not shown) are well known in the art, and, for the sake of brevity and conciseness, will not be described or illustrated herein.

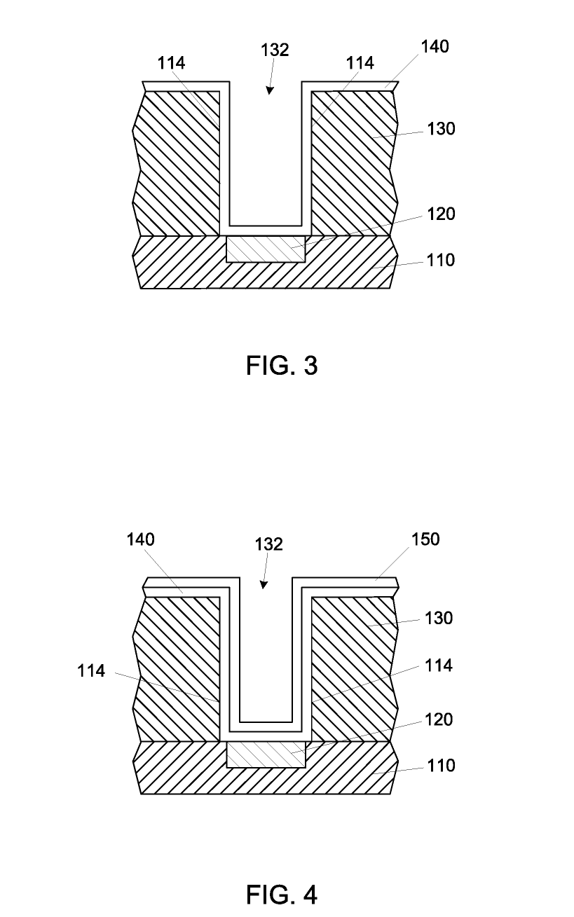

As shown in FIG. 3, a barrier layer 140 may be formed on sidewalls 114 of the opening 132, as well as on the exposed portion 122 (see FIG. 2) of the conductive land 120. The barrier layer 140 may be made of any appropriate material, including but not limited to, titanium, tantalum, tungsten, manganese, niobium, molybdenum, and cobalt, as well as nitrides, borides, carbides, and silicides thereof. The barrier layer 140 may be formed by any known process, including but not limited to physical vapor deposition, chemical vapor deposition, atomic layer deposition, electroless plating, electroplating, and the like. In an embodiment of the present description, the barrier layer 140 may be formed by a conformal deposition process resulting in a substantially conformal barrier layer 140. Although the barrier layer 140 is illustrated as a single layer, it is understood that the barrier layer 140 may be a plurality of layers. As will be understood to those skilled in the art, the barrier layer 140 may be used to prevent subsequently deposited materials from migrating into the first dielectric material layer 110 and the second dielectric material layer 130.

As shown in FIG. 4, a ruthenium-containing liner 150 may be formed on the barrier layer 140. In an embodiment, the ruthenium-containing liner 150 may be deposited by any known process, including but not limited to physical vapor deposition, chemical vapor deposition, atomic layer deposition, electroless plating, electroplating, and the like. In an embodiment of the present description, the ruthenium-containing liner 150 may be formed by a conformal deposition process resulting in a substantially conformal ruthenium-containing liner 150. It is understood, that the ruthenium-containing liner 150 may be used for its high adhesion and wetting properties for a subsequently deposited copper fill material, as will be discussed. In one embodiment, the ruthenium-containing liner 150 is substantially pure ruthenium.

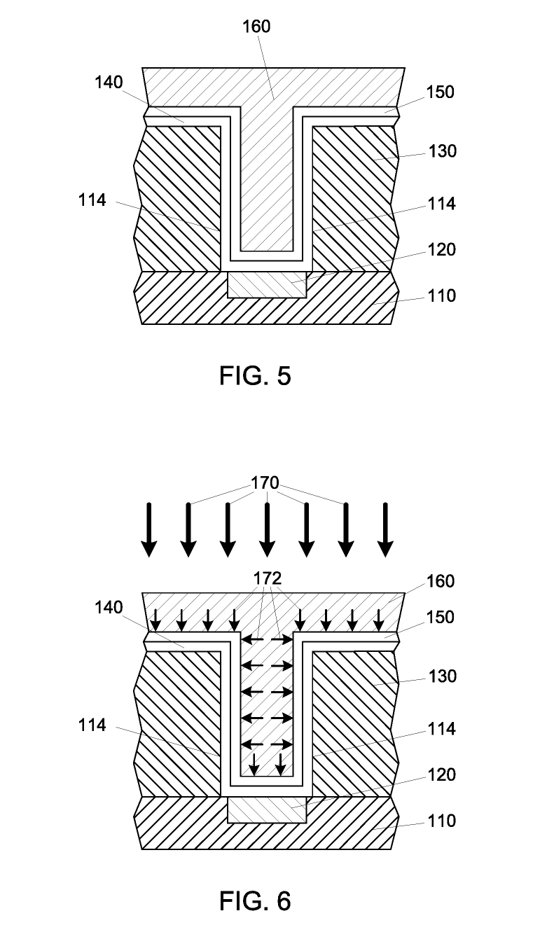

As shown in FIG. 5, a copper/aluminum alloy fill material 160 may be deposited in the opening 132 (see FIG. 4) to abut the ruthenium-containing liner 150. In one embodiment, the copper/aluminum alloy fill material 160 may be formed by any known process, including but not limited to physical vapor deposition, chemical vapor deposition, atomic layer deposition, electroless plating, electroplating, and the like. In one embodiment, the copper/alloy fill material 160 may comprise an aluminum content of between about 1% and 20% atomic.

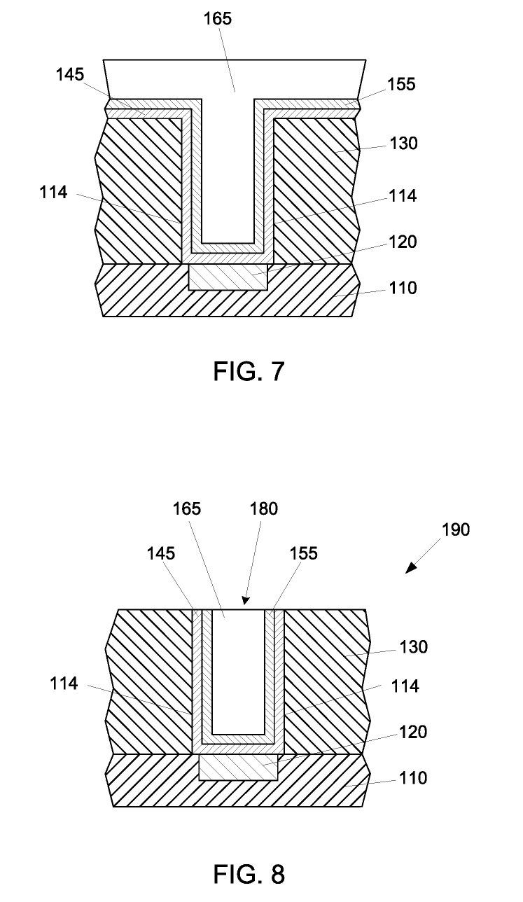

As shown in FIG. 6, the copper/aluminum alloy fill material 160 may be annealed/heated (shown as arrows 170) to migrate (shown as arrows 172) the aluminum within the copper/aluminum alloy fill material 160 into the ruthenium-containing liner 150. The migration of the aluminum 172, as shown in FIG. 6 forms, a ruthenium/aluminum-containing liner 155 and a substantially aluminum-free copper fill material 165, as shown in FIG. 7. For the purposes for the present description, the term “substantially aluminum-free” is defined to mean an aluminum content of less than about 3% atomic. Furthermore, the annealing 170 may also result in the migration of the aluminum into the barrier layer 140 to form an aluminum-containing barrier layer 145. In one embodiment, the annealing 170 may be performed at a temperature of between about 250° C. and 400° C. for a sufficient duration of time to effectuate the aluminum migration. It noted that the shading in the copper/aluminum alloy fill material 160 (see FIG. 5) has been transferred into the ruthenium/aluminum-containing liner 155 and the aluminum-containing barrier layer 145 to represent the transfer of the aluminum.

As shown in FIG. 8, any portion of the substantially aluminum-free copper fill material 165, the ruthenium/aluminum-containing liner 155, and/or the aluminum-containing barrier layer 145 which may extend over the second dielectric material layer 120 outside of the opening 132 (see FIG. 6) may be removed, such as by chemical mechanical polishing, to form at least one conductive connector 180 for a microelectronic structure 190.

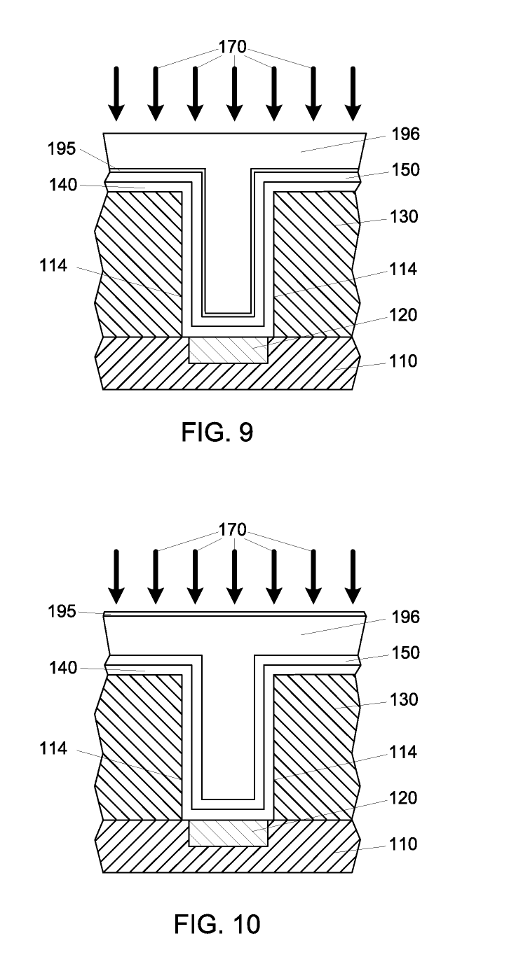

In another embodiment, beginning with FIG. 5, an aluminum layer 195 may be deposited on the ruthenium-containing liner 150 followed by the deposition of a copper fill material 196, as shown in FIG. 9. As further shown in FIG. 9, an annealing 170 may be performed, as previously discussed, to form the ruthenium/aluminum-containing liner 155 and the substantially aluminum-free copper fill material 165, as shown in FIG. 7. It is understood, the annealing 170 may be performed prior to the deposition of the copper fill material 196.

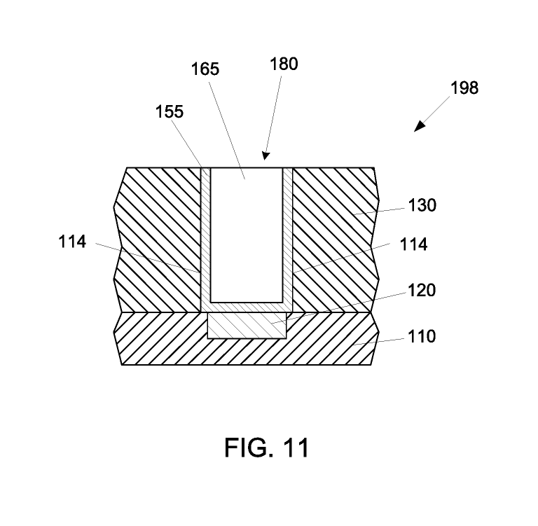

In another embodiment, beginning with FIG. 5, the copper fill material 196 may be deposited to abut the ruthenium-containing liner 150 followed by the deposition of the aluminum layer 195 on copper fill material 196, as shown in FIG. 10. As further shown in FIG. 10, an annealing 170 may be performed, as previously discussed, which migrates the aluminum layer 195 through the copper fill material 196 to form the ruthenium/aluminum-containing liner 155 and the substantially aluminum-free copper fill material 165, as shown in FIG. 7.

In still another embodiment, the ruthenium/aluminum-containing liner 155, as shown in FIG. 6, may also act as a barrier layer, i.e. prevent subsequently deposited materials from migrating into the first dielectric material layer 110 and the second dielectric material layer 130, such that a barrier layer is not required. Thus, all of the previously describe processes may be followed, with the exception of forming the barrier layer 140 (see FIG. 4) and/or the aluminum-containing barrier layer 145 (see FIG. 6), to form a microelectronic structure 198, wherein the ruthenium/aluminum-containing liner 155 abuts the second dielectric material layer 130, the conductive land 120, and/or the first dielectric material layer 110, as shown in FIG. 11.

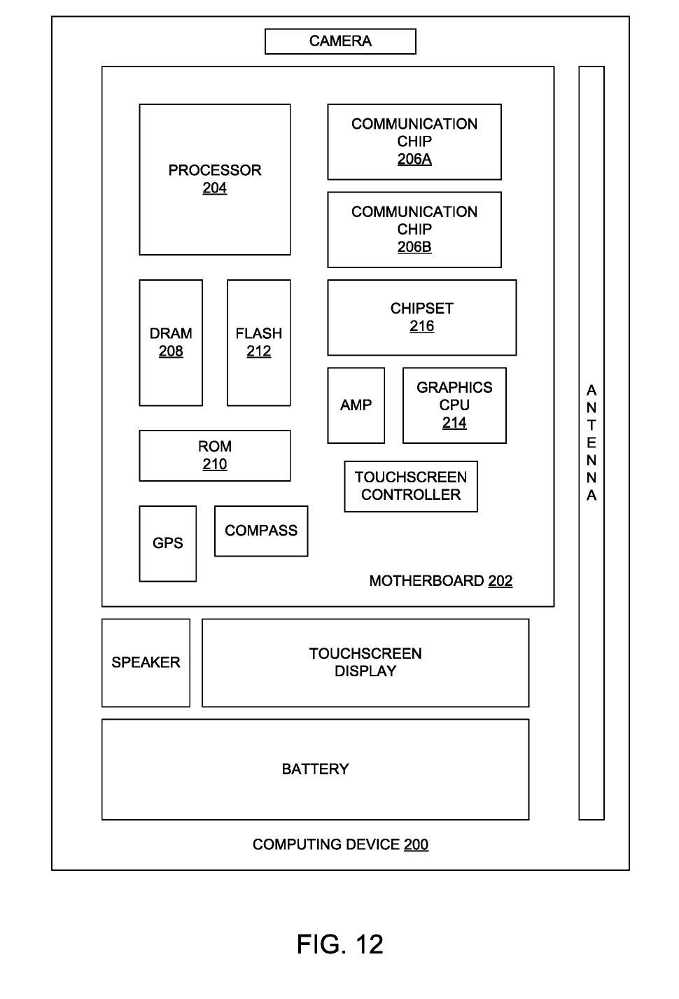

FIG. 12 illustrates a computing device 200 in accordance with one implementation of the present description. The computing device 200 houses a board 202. The board may include a number of microelectronic components, including but not limited to a processor 204, at least one communication chip 206A, 206B, volatile memory 208, (e.g., DRAM), non-volatile memory 210 (e.g., ROM), flash memory 212, a graphics processor or CPU 214, a digital signal processor (not shown), a crypto processor (not shown), a chipset 216, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker (not shown), a camera, and a mass storage device (not shown) (such as hard disk drive, compact disk (CD), digital versatile disk (DVD), and so forth). Any of the microelectronic components may be physically and electrically coupled to the board 202. In some implementations, at least one of the microelectronic components may be a part of the processor 204.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

Any of the microelectronic components within the computing device 400 may include a microelectronic structure comprising a dielectric material layer over a conductive land, an opening extending through the dielectric material layer to a portion of the conductive land, a ruthenium/aluminum-containing liner adjacent at least one sidewall of the opening and adjacent the conductive land, and a substantially aluminum-free copper fill material abutting the ruthenium/aluminum-containing liner.

In various implementations, the computing device may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-11. The subject matter may be applied to other microelectronic device and assembly applications, as will be understood to those skilled in the art.

The following examples pertain to further embodiments, wherein Example 1 is a microelectronic structure, comprising a dielectric material layer over a conductive land, an opening extending through the dielectric material layer exposing a portion of the conductive land, a ruthenium/aluminum-containing liner adjacent at least one sidewall of the opening and adjacent the conductive land; and a substantially aluminum-free copper fill material abutting the ruthenium/aluminum-containing liner.

In Example 2, the subject matter of Example 1 can optionally include the ruthenium/aluminum-containing liner abuts the at least one opening sidewall and abuts the conductive land.

In Example 3, the subject matter of Example 1 can optionally include a barrier layer between the opening sidewalls and the ruthenium/aluminum-containing liner.

In Example 4, the subject matter of Example 3 can optionally include the barrier layer comprising a material selected from the group consisting of titanium, tantalum, tungsten, manganese, niobium, molybdenum, and cobalt, and nitrides, borides, carbides, and silicides thereof.

The following examples pertain to further embodiments, wherein Example 5 is a method of fabricating a microelectronic structure, comprising forming a dielectric material layer over a conductive land, forming an opening through the dielectric material layer to expose a portion of the conductive land, forming a ruthenium/aluminum-containing liner adjacent at least one sidewall of the opening and adjacent the exposed portion of the conductive land, and forming a substantially aluminum-free copper fill material abutting the ruthenium/aluminum-containing liner.

In Example 6, the subject matter of Example 5 can optionally include forming a barrier layer between the opening sidewalls and the ruthenium/aluminum-containing liner.

In Example 7, the subject matter of Example 6 can optionally include forming the barrier layer from a material selected from the group consisting of titanium, tantalum, tungsten, manganese, niobium, molybdenum, and cobalt, and nitrides, borides, carbides, and silicides thereof.

In Example 8,the subject matter of Example 5 can optionally include forming the ruthenium/aluminum-containing liner and forming the substantially aluminum-free copper fill material comprising depositing a ruthenium-containing liner adjacent the at least one sidewall of the opening, depositing a copper/aluminum alloy fill material abutting the ruthenium-containing liner, and annealing the ruthenium-containing liner and the copper/aluminum alloy to migrate the aluminum from the copper/aluminum alloy fill material into the ruthenium-containing liner.

In Example 9, the subject matter of Example 8 can optionally include forming a barrier layer between the opening sidewalls and the ruthenium/aluminum-containing liner.

In Example 10, the subject matter of Example 9 can optionally include annealing the ruthenium-containing liner and the copper/aluminum alloy migrates the aluminum from the copper/aluminum alloy fill material into the barrier layer.

In Example 11, the subject matter of either Examples 8 or 9 can optionally include forming the barrier layer from a material selected from the group consisting of titanium, tantalum, tungsten, manganese, niobium, molybdenum, and cobalt, and nitrides, borides, carbides, and silicides thereof.

In Example 12, the subject matter of Example 5 can optionally include depositing the copper/aluminum alloy fill material having an aluminum content of between about 1% and 20% atomic.

In Example 13, the subject matter of Example 5 can optionally include forming the ruthenium/aluminum-containing liner and forming the substantially aluminum-free copper fill material comprising depositing a ruthenium-containing liner adjacent the at least one sidewall of the opening, depositing an aluminum layer abutting the ruthenium-containing liner, depositing a copper fill material abutting the ruthenium-containing liner, and annealing the aluminum layer to migrate it into the ruthenium-containing liner.

In Example 14, the subject matter of Examples 13 can optionally include annealing the aluminum layer prior to depositing the copper fill material.

In Example 15, the subject matter of Examples 13 can optionally include forming a barrier layer between the opening sidewalls and the ruthenium/aluminum-containing liner.

In Example 16, the subject matter of Examples 15 can optionally include annealing the aluminum layer to migrate a portion thereof into the barrier layer.

In Example 17, the subject matter of either Examples 15 or 16 can optionally include forming the barrier layer from a material selected from the group consisting of titanium, tantalum, tungsten, manganese, niobium, molybdenum, and cobalt, and nitrides, borides, carbides, and silicides thereof.

In Example 18, the subject matter of Example 5 can optionally include forming the ruthenium/aluminum-containing liner and forming the substantially aluminum-free copper fill material comprising depositing a ruthenium-containing liner adjacent the at least one sidewall of the opening, depositing a copper fill material abutting the ruthenium-containing liner, depositing an aluminum layer abutting the copper fill material, and annealing the aluminum layer to migrate it into the ruthenium-containing liner.

In Example 19, the subject matter of Examples 18 can optionally include forming a barrier layer between the opening sidewalls and the ruthenium/aluminum-containing liner.

In Example 20, the subject matter of Examples 19 can optionally include annealing the aluminum layer to migrate a portion thereof into the barrier layer.

In Example 21, the subject matter of either Examples 19 or 20 can optionally include forming the barrier layer from a material selected from the group consisting of titanium, tantalum, tungsten, manganese, niobium, molybdenum, and cobalt, and nitrides, borides, carbides, and silicides thereof.

The following examples pertain to further embodiments, wherein Example 22 is an electronic system comprising a board and a microelectronic component attached to the board, wherein at least one of the microelectronic component and the board, include a conductive connector, comprising a dielectric material layer over a conductive land, an opening extending through the dielectric material layer exposing a portion of the conductive land, a ruthenium/aluminum-containing liner adjacent at least one sidewall of the opening and adjacent the conductive land, and a substantially aluminum-free copper fill material abutting the ruthenium/aluminum-containing liner.

In Example 23, the subject matter of Example 22 can optionally include the ruthenium/aluminum-containing liner abutting the at least one opening sidewall and abutting the conductive land.

In Example 24, the subject matter of Example 22 can optionally include a barrier layer between the opening sidewalls and the ruthenium/aluminum-containing liner.

In Example 25, the subject matter of Example 24 can optionally include the barrier layer comprising a material selected from the group consisting of titanium, tantalum, tungsten, manganese, niobium, molybdenum, and cobalt, and nitrides, borides, carbides, and silicides thereof.

Having thus described in detail embodiments of the present description, it is understood that the present description defined by the appended claims is not to be limited by particular details set forth in the above description, as many apparent variations thereof are possible without departing from the spirit or scope thereof.

1-25. (canceled)

26. A microelectronic structure, comprising:
a dielectric material layer over a conductive land;
an opening extending through the dielectric material layer exposing at least a portion of the conductive land;
a ruthenium/aluminum-containing liner adjacent at least one sidewall of the opening and adjacent the conductive land; and
a substantially aluminum-free copper fill material abutting the ruthenium/aluminum-containing liner.

27. The microelectronic structure of claim 26, wherein the ruthenium/aluminum-containing containing liner abuts the at least one opening sidewall and abuts the conductive land.

28. The microelectronic structure of claim 26, further including a barrier layer between the opening sidewalls and the ruthenium/aluminum-containing liner.

29. The microelectronic structure of claim 28, wherein the barrier layer comprises a material selected from the group consisting of titanium, tantalum, tungsten, manganese, niobium, molybdenum, and cobalt, and nitrides, borides, carbides, and silicides thereof.

30. A method of fabricating a microelectronic structure, comprising:
forming a dielectric material layer over a conductive land;
forming an opening through the dielectric material layer to expose at least a portion of the conductive land;
forming a ruthenium/aluminum-containing liner adjacent at least one sidewall of the opening and adjacent the exposed portion of the conductive land; and
forming a substantially aluminum-free copper fill material abutting the ruthenium/aluminum-containing liner.

31. The method of claim 30, further including forming a barrier layer between the opening sidewalls and the ruthenium/aluminum-containing liner.

32. The method of claim 31, wherein forming the barrier layer comprises forming the barrier layer from a material selected from the group consisting of titanium, tantalum, tungsten, manganese, niobium, molybdenum, and cobalt, and nitrides, borides, carbides, and silicides thereof.

33. The method of claim 30, wherein forming the ruthenium/aluminum-containing liner and forming the substantially aluminum-free copper fill material comprises:
depositing a ruthenium-containing liner adjacent the at least one sidewall of the opening;
depositing a copper/aluminum alloy fill material abutting the ruthenium-containing liner; and
annealing the ruthenium-containing liner and the copper/aluminum alloy to migrate the aluminum from the copper/aluminum alloy fill material into the ruthenium-containing liner.

34. The method of claim 33, further including forming a barrier layer between the opening sidewalls and the ruthenium/aluminum-containing liner.

35. The method of claim 34, wherein annealing the ruthenium-containing liner and the copper/aluminum alloy migrates the aluminum from the copper/aluminum alloy fill material into the barrier layer.

36. The method of claim 33, wherein forming the barrier layer comprises forming the barrier layer from a material selected from the group consisting of titanium, tantalum, tungsten, manganese, niobium, molybdenum, and cobalt, and nitrides, borides, carbides, and silicides thereof.

37. The method of claim 30, wherein depositing the copper/aluminum alloy fill material comprises depositing the copper/aluminum alloy fill material having an aluminum content of between about 1% and 20% atomic.

38. The method of claim 30, wherein forming the ruthenium/aluminum-containing liner and forming the substantially aluminum-free copper fill material comprises:
depositing a ruthenium-containing liner adjacent the at least one sidewall of the opening;
depositing an aluminum layer abutting the ruthenium-containing liner;
depositing a copper fill material abutting the ruthenium-containing liner; and
annealing the aluminum layer to migrate it into the ruthenium-containing liner.

39. The method of claim 38, wherein annealing the aluminum layer occurs prior to depositing the copper fill material.

40. The method of claim 38, further including forming a barrier layer between the opening sidewalls and the ruthenium/aluminum-containing liner.

41. The method of claim 40, wherein annealing the aluminum layer migrates a portion thereof into the barrier layer.

42. The method of claim 40, wherein forming the barrier layer comprises forming the barrier layer from a material selected from the group consisting of titanium, tantalum, tungsten, manganese, niobium, molybdenum, and cobalt, and nitrides, borides, carbides, and silicides thereof.

43. The method of claim 30, wherein forming the ruthenium/aluminum-containing liner and forming the substantially aluminum-free copper fill material comprises:
depositing a ruthenium-containing liner adjacent the at least one sidewall of the opening;
depositing a copper fill material abutting the ruthenium-containing liner;
depositing an aluminum layer abutting the copper fill material; and
annealing the aluminum layer to migrate it through the copper fill material and into the ruthenium-containing liner.

44. The method of claim 43, further including forming a barrier layer between the opening sidewalls and the ruthenium/aluminum-containing liner.

45. The method of claim 44, wherein annealing the aluminum layer migrates a portion thereof into the barrier layer.

46. The method of claim 44, wherein forming the barrier layer comprises forming the barrier layer from a material selected from the group consisting of titanium, tantalum, tungsten, manganese, niobium, molybdenum, and cobalt, and nitrides, borides, carbides, and silicides thereof.

47. An electronic system, comprising
a board; and
a microelectronic component attached to the board, wherein at least one of the microelectronic component and the board, includes a conductive connector, comprising:
a dielectric material layer over a conductive land;
an opening extending through the dielectric material layer exposing at least a portion of the conductive land;
a ruthenium/aluminum-containing liner adjacent at least one sidewall of the opening and adjacent the conductive land; and
a substantially aluminum-free copper fill material abutting the ruthenium/aluminum-containing liner.

48. The electronic system of claim 47, wherein the ruthenium/aluminum-containing liner abuts the at least one opening sidewall and abuts the conductive land.

49. The electronic system of claim 47, further including a barrier layer between the opening sidewalls and the ruthenium/aluminum-containing liner.

50. The electronic system of claim 49, wherein the barrier layer comprises a material selected from the group consisting of titanium, tantalum, tungsten, manganese, niobium, molybdenum, and cobalt, and nitrides, borides, carbides, and silicides thereof.
